(19) United States
(12) Patent Application Publication
(10) Pub. No.: US 2016/0173071 A1
(43) Pub. Date: Jun. 16, 2016

(54) CLOCK-DISTRIBUTION DEVICE AND CLOCK-DISTRIBUTION METHOD

(71) Applicant: MediaTek Singapore Pte. Ltd., Singapore (SG)

(72) Inventors: Lan-Sin LIAU, Buangkok (SG); Kai-Hsin CHEN, Changhua City (TW); Jiaying CHEN, Singapore (SG)

(21) Appl. No.: 14/828,778

(22) Filed: Aug. 18, 2015

Related U.S. Application Data
(60) Provisional application No. 62/089,990, filed on Dec. 10, 2014.

(51) Int. Cl. H03K 5/05

(52) U.S. Cl. CPC H03K 5/05

(57) ABSTRACT

A clock-distribution device for dividing a clock signal into a plurality of clock signals for a plurality of registers is provided. The clock-distribution device includes at least one mesh driver and a clock mesh. The mesh driver is coupled to an input port of the clock-distribution device to transmit and divide the clock signal from the input port. The clock mesh is driven by the mesh driver and is utilized to uniformly distribute the clock signals for the registers.

### CROSS REFERENCE TO RELATED APPLICATIONS

This application claims the benefit of U.S. Provisional Application No. 62/089,990, filed Dec. 10, 2014, the entirety of which is incorporated by reference herein.

### BACKGROUND OF THE INVENTION

1. Field of the Invention

The present inventive concept relates to a clock-distribution device. More particularly, the inventive concept relates to a clock-distribution device with a clock mesh and mesh drivers.

2. Description of the Related Art

In order to access and use semiconductor devices properly, it is necessary to distribute clock signals to its parallel sequential elements at approximately the same time within the semiconductor devices. For example, the parallel sequential elements could include registers, flip-flops, latches and memory. When clock signals arrive at these parallel sequential elements at different times, clock skew may occur. Accordingly, the clock skew could cause a variety of problems including setup and hold violations. The integrity of data transmitted along the semiconductor device could be affected, and the performance of the semiconductor device could deteriorate. Therefore, an efficient clock-distribution device and an efficient clock-distribution method are needed to reduce clock skew and prevent performance deterioration.

### BRIEF SUMMARY OF THE INVENTION

The present invention provides a clock-distribution device for dividing a clock signal into a plurality of clock signals for a plurality of registers. The clock-distribution device includes at least one mesh driver and a clock mesh. The mesh driver is coupled to an input port of the clock-distribution device to transmit and/or divide the clock signal from the input port. The clock mesh is driven by the mesh driver and utilized to distribute the clock signals for the registers uniformly.

The present invention provides a clock-distribution device for dividing a clock signal into a plurality of clock signals for a plurality of registers. The clock-distribution device includes a plurality of clock gates and a clock mesh. The clock gates are utilized to transmit the clock signals to the registers. The clock mesh is arranged between the clock gates and an input port of the clock-distribution device. The clock mesh is utilized to distribute the clock signals to the clock gates uniformly. The clock signals are provided from the input port.

In an aspect of the present invention, the clock-distribution device further includes at least one mesh driver arranged between the clock mesh and the input port to drive the clock mesh, includes at least one pre-mesh driver arranged between the mesh driver and the input port to drive the mesh driver, and includes at least one buffer arranged between the pre-mesh driver and the input port to transmit the clock signal from the input port to the pre-mesh driver. The number of mesh drivers and pre-mesh drivers is determined by the number of registers and/or transition of the clock signal.

In another aspect of the present invention, the input port is coupled to a clock-generation module to receive the clock signal generated by the clock-generation module. The clock gates connect to a plurality of output ports of the clock-distribution device, and the clock-distribution device transmits the clock signals to the registers through the output ports. In addition, the configuration of the clock mesh is determined by the number of registers and/or transition of the clock signal. The number of clock gates is proportional to the number of registers.

The present invention provides a clock-distribution method for dividing a clock signal into a plurality of clock signals for a plurality of registers. The clock-distribution method includes determining number of registers and a transition of the clock signal; arranging a plurality of clock gates which connect to a plurality of output ports; arranging at least one buffer between the mesh driver and the input port to transmit the clock signal from the input port to the mesh driver; arranging a clock mesh to uniformly distribute the clock signals for the registers; arranging at least one mesh driver to transmit and/or divide the clock signal from an input port; routing the clock mesh and simulating the timing of the clock signals.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic diagram of the clock-distribution device according to the present invention;

FIG. 2 is another schematic diagram of the clock-distribution device according to the present invention;

FIG. 3 is another schematic diagram of the clock-distribution device according to the present invention;

FIG. 4 is a schematic diagram of the clock-distribution device, the clock-generation device and registers according to the present invention;

FIG. 5A to FIG. 5D are schematic diagrams illustrating the arrangements of the clock-distribution device according to the present invention;

FIG. 6 is a flow chart illustrating the clock-distribution method according to the present invention.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF THE INVENTION

The following description is of the best-contemplated operation of carrying out the invention. This description is made for the purpose of illustrating the general principles of the invention and should not be taken in a limiting sense. Certain terms and figures are used throughout the description and following claims to refer to particular components. As one skilled in the art will appreciate, manufacturers may refer to a component by different names. This document does not intend to distinguish between components that differ in name but not function. The terms “component”, “system” and “device” used in the present invention could be the entity relating to the computer which is hardware, software, or a combination of hardware and software. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

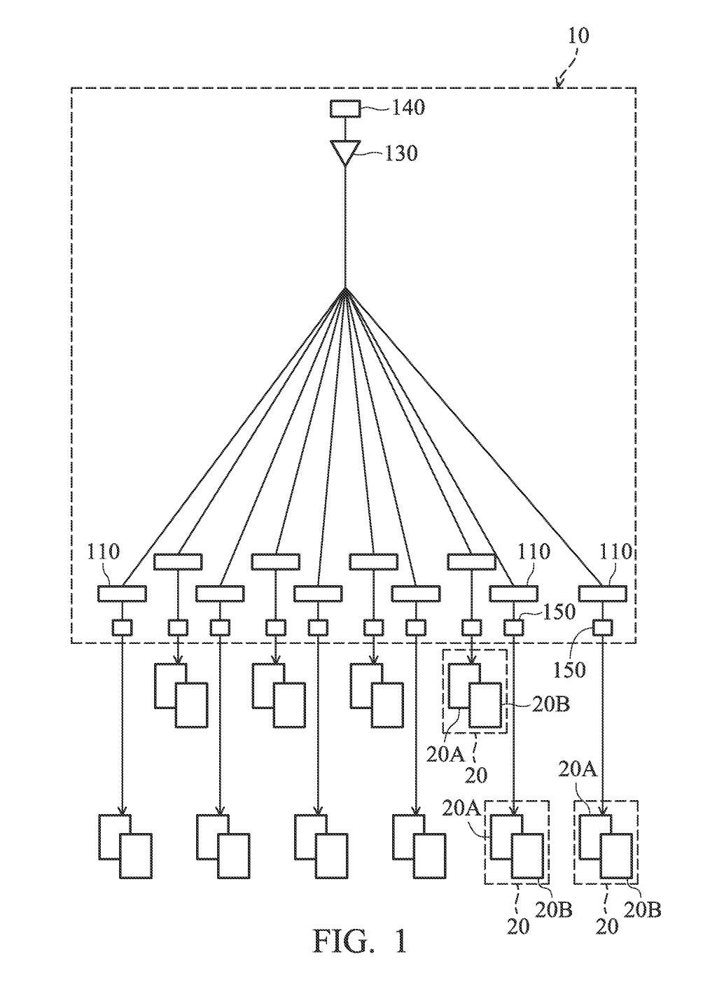

FIG. 1 is a schematic diagram of the clock-distribution device 10 according to the present invention. The clock-distribution device 10 could be arranged within a semiconductor device and utilized for a processor. The processor could include a digital signal processor (DSP), a microcontroller (MCU), a central-processing unit (CPU) or a plurality of parallel processors relating the parallel processing environment to implement the operating system (OS), firmware, driver and/or other applications of an electronic device. The electronic device mentioned above could be a mobile electronic device such as a cell phone, a tablet computer, a laptop computer or a PDA, or could it be an electronic device such as a desktop computer or a server.

The clock-distribution device 10 and a plurality of registers 20 are illustrated in FIG. 1. The clock-distribution device 10 is utilized for dividing a clock signal into a plurality of clock signals for the registers 20. The register 20 could include more than one register such as the sub-register 20A and the sub-register 20B. The number and the type of the register 20 are not limited. In one embodiment, the clock-distribution device 10 includes a buffer 130, an input port 140, at least one clock gate 110 and at least one output port 150 as shown in FIG. 1. The input port 140 is utilized to receive a clock signal. The buffer 130 is coupled between the input port 140 and the clock gates 110 to transmit the clock signal from the input port 140 to each of the clock gates 110. Each of the clock gates 110 connects to each of the respective output ports 150. Therefore, the clock signal could be transmitted from the clock-distribution device 10 to the registers 20 through the output ports 150.

In the embodiment as shown in FIG. 1, the clock signals are distributed by the clock-distribution device 10 and provided for the registers 20. However, the clock signals could not be received by each of the registers 20 at the same time, which result in the clock skew for the clock-distribution device 10 and the registers 20. The performance of the clock-distribution device 10 and the registers 20 may be degraded accordingly. In addition, the clock-distribution device 10 is a flattened design, which means that the clock signal is directly transmitted from the buffer 130 to the clock gates 150. There, it consumes time (for example, 1 hour) to generate output files such as SPEF files and netlist files.

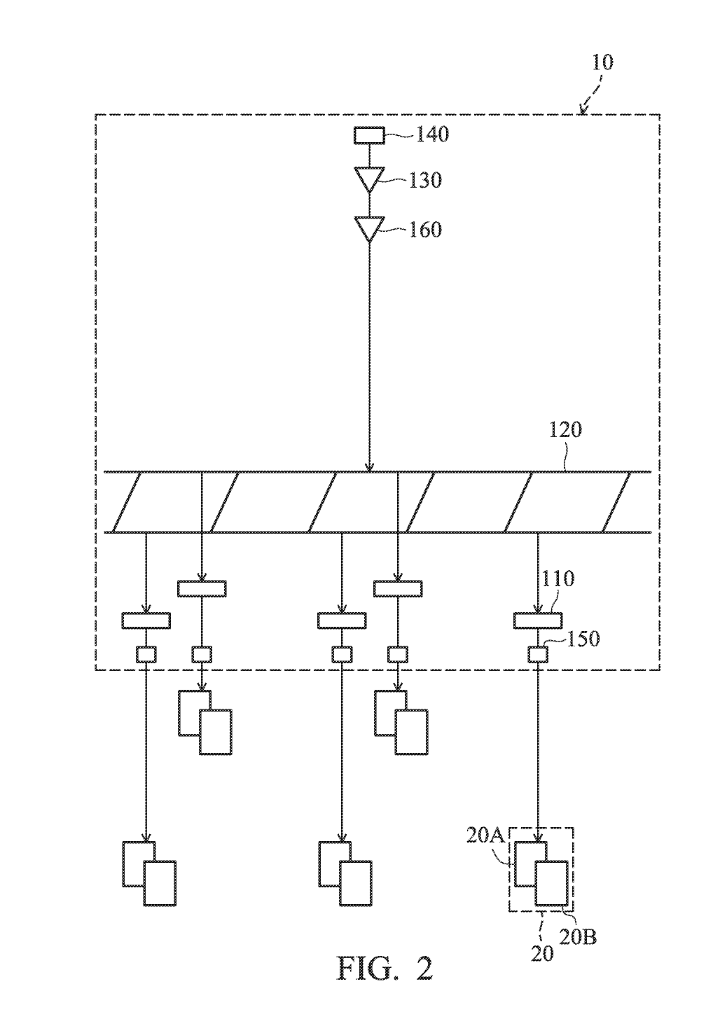

FIG. 2 is another schematic diagram of the clock-distribution device 10 according to the present invention. As shown in FIG. 2, the clock-distribution device 10 includes at least one buffer 130, an input port 140, a clock mesh 120, at least one clock gate 110, at least one mesh driver 160 and at least one output port 150. The input port 140 is utilized to receive a clock signal. The buffer 130 is coupled between the input port 140 and the mesh drivers 160 to transmit the clock signal from the input port 140 to the mesh drivers 160. In addition, the mesh drivers 160 are coupled between the buffer 130 and the clock mesh 120 to drive the clock mesh 120.

In one embodiment, the clock mesh 120 is arranged between the clock gates 110 and the mesh drivers 160 to distribute the clock signals to the clock gates 110 uniformly. In other words, the clock signals arrive at each of the clock gates 110 at approximately the same time. Compared with the embodiment of FIG. 1, clock skew could be reduced due to the arrangement of the clock mesh 120 as shown in FIG. 2. It should be noted that the clock mesh 120 is laid uniformly across the clock gates 110 to reduce the variation of distance and the variation of the RC delay between the clock mesh 120 and the clock gates 110. As such, the clock signals could be received by each of the clock gates almost at the same time to reduce the clock skew. Furthermore, each of the clock gates 110 connects to each of the respective output ports 150. Therefore, the clock signals could be distributed by the clock-distribution device 10 and transmitted to each of the registers 20.

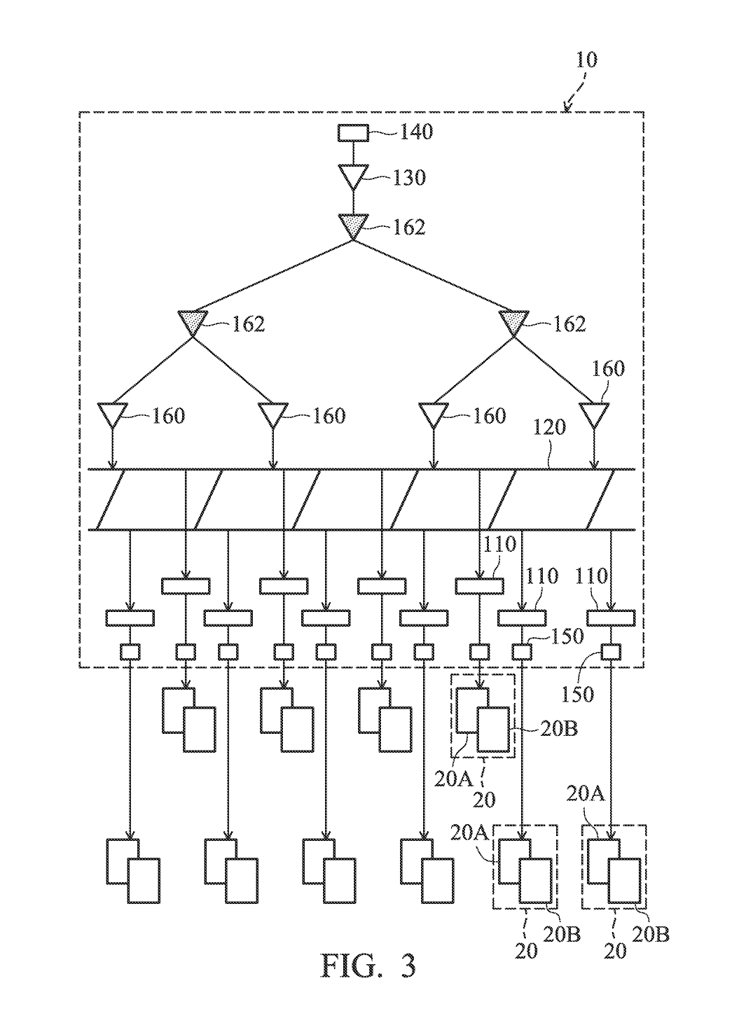

FIG. 3 is another schematic diagram of the clock-distribution device 10 according to the present invention. As shown in FIG. 3, the clock-distribution device 10 includes at least one buffer 130, an input port 140, a clock mesh 120, at least one clock gate 110, at least one mesh driver 160, at least one pre-mesh drivers and at least one output port 150. The input port 140 is utilized to receive a clock signal. The buffer 130 is coupled between the input port 140 and the pre-mesh drivers 162 to transmit the clock signal from the input port 140 to the pre-mesh drivers 162. Specifically, the pre-mesh drivers 162 are coupled between the buffer 130 and the mesh drivers 160 to drive the mesh drivers 160. The mesh drivers 160 are coupled between the pre-mesh drivers 162 and the clock mesh 120 to drive the clock mesh 120. Afterwards, the clock mesh 120 is utilized to uniformly distribute the clock signals to the clock gates 110.

It should be noted that the number of registers 20 in FIG. 3 is higher than the number of registers 20 in FIG. 2, which means that the loading for the clock-distribution device 10 of FIG. 3 is heavier than the loading for the clock-distribution device 10 of FIG. 2. Therefore, compared with the embodiment of FIG. 2, more clock gates 110 are arranged for transmitting the clock signals, and more mesh drivers 160 and pre-mesh drivers 162 are arranged to drive the clock mesh 120 for distributing the clock signals. In other words, the number of clock gates 110 is proportional to the number of registers 20. The number of clock gates 110 should be increased when the number of registers 20 increases. In addition, the number of the mesh drivers 160 and the pre-mesh drivers 162 is also determined by the number of registers 20. The number of the mesh drivers 160 and the pre-mesh drivers 162 should be increased correspondingly when the number of registers 20 increases.

In another embodiment, the number of mesh drivers 160 and pre-mesh drivers 162 is also determined by the transition of the clock signal. The clock signal includes two different states, and it switches between the two states alternatively. The transition of clock signal indicates the rate and speed it switches between the two different states. More specifically, the number of mesh drivers 160 and the pre-mesh drivers 162 is proportional to the transition of the clock signals. When the transition of the clock signals increases, more driving capacity will be needed corresponding to the high-speed transition. Therefore, the number of mesh drivers 160 and pre-mesh drivers 162 should be increased for obtaining a high driving capacity.

Furthermore, when the loading of the clock-distribution device 10 increases, the transition of the clock signals will be decreased. When the transition of the clock signal is pre-determined and fixed due to the design requirement of the semiconductor device, the loading of the clock-distribution device 10 should also be arranged within the certain range and limitation. Therefore, the configuration of the clock mesh 120 and the arrangement of the mesh drivers 160 and pre-mesh drivers 162 could be determined according to the synergy of both the transition of the clock signal and the loading of the clock-distribution device 10.

In the embodiment of FIG. 3, the clock mesh 120 is laid uniformly across the clock gates 110 to reduce the variation of distance and the variation of the RC delay between the clock mesh 120 and the clock gates 110. As such, the clock signals could be received by each of the clock gates 110 at almost the same time to reduce the clock skew. Compared with the embodiments of top-level design where the registers 20, the clock-generation device 30 and the clock gates 110 are flattened design, less time is required to generate output files by the clock-distribution device 10 of FIG. 3.

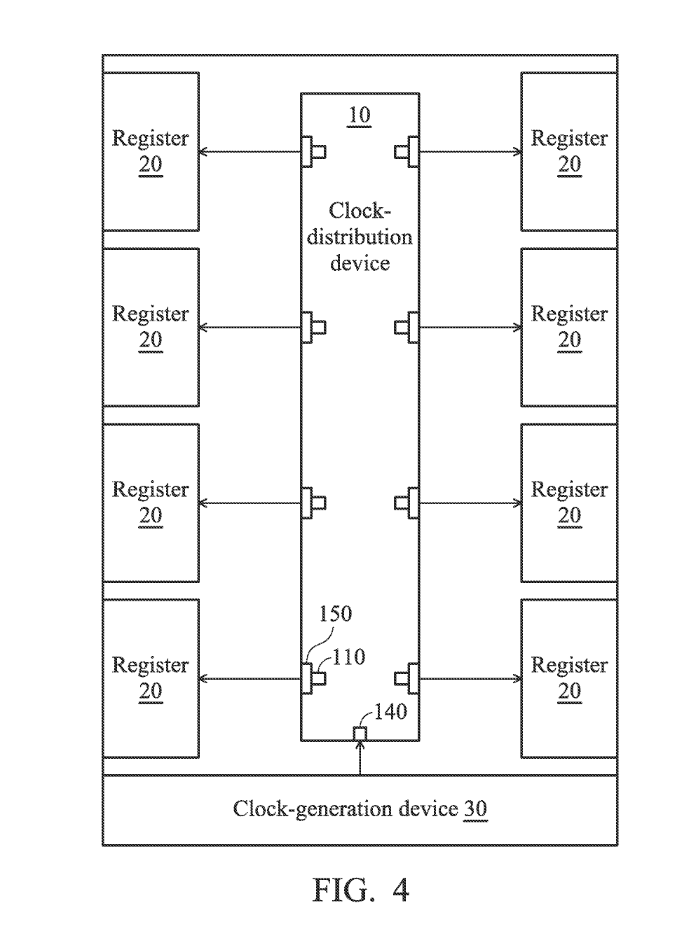

FIG. 4 is a schematic diagram of the clock-distribution device 10, the clock-generation device 30 and registers 20 according to the present invention. The clock signal is generated by the clock-generation device 30 and transmitted to the clock-distribution device 10 through the input port 140. Afterwards, the clock-distribution device 10 divides the clock signal into a plurality of clock signals and distributes them uniformly to the registers 20. It should be noted that the configuration and shape of the clock-distribution device are determined based on the arrangement of the registers 20 surrounding the clock-distribution device 10. For example, the shape of the clock-distribution device 10 is rectangular as shown in FIG. 4. The shape of the clock-distribution device 10 could be adjusted corresponding to the number of registers 20 and the arrangement positions of the registers 20.

Regarding the configuration of the clock-distribution device 10, the arrangement of the input port 140, the clock gates 110 and the output ports 150 of the clock-distribution device 10 are also determined in accordance with the number and arrangement positions of the registers 20 and the clock-generation device 30. Accordingly, the clock mesh 120 and it related mesh drivers 160 and pre-mesh drivers 162 are also determined in accordance with the arrangement and positions of the registers 20 and the clock-generation device 30. For example, when lots of registers 20 are arranged, a great number of mesh-drivers 160 and pre-mesh drivers 162 will be needed for the clock-distribution device 10. In order to drive the clock mesh 120 properly and efficiently, the mesh-drivers 160 and pre-mesh drivers 162 could be arranged in a tree-structure with multiple points.

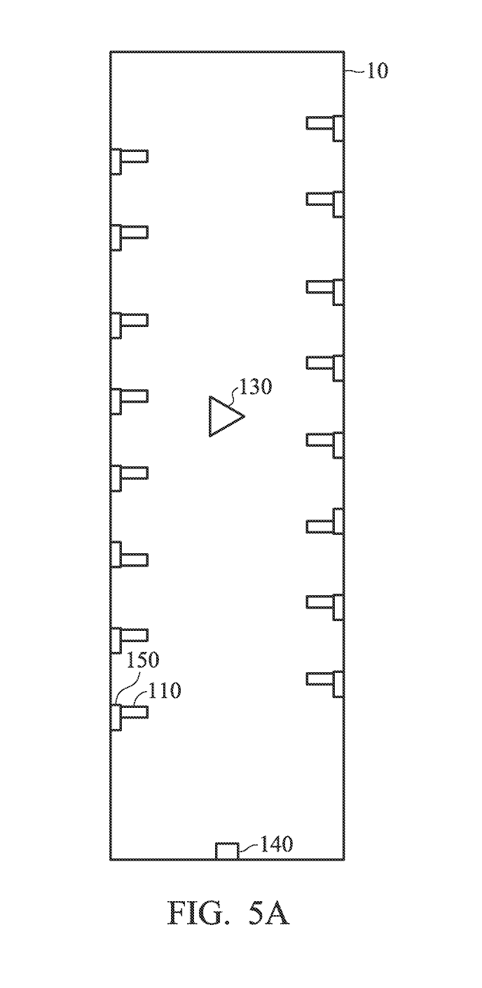

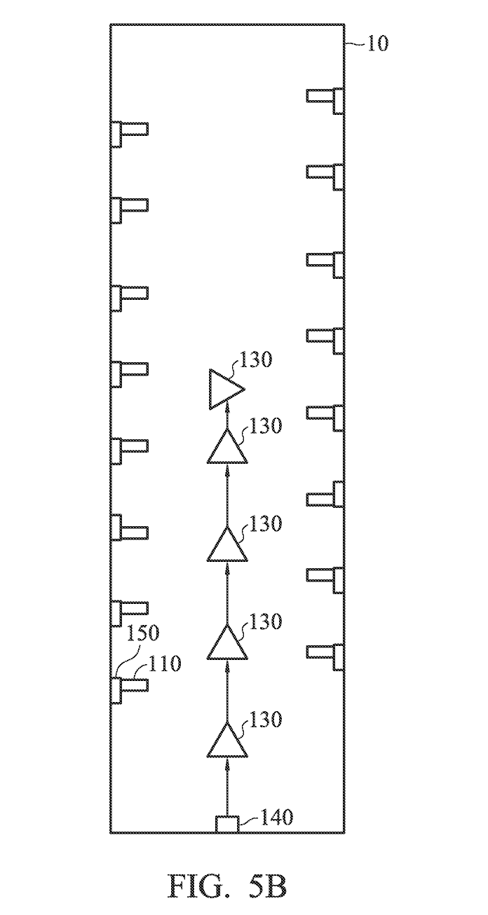

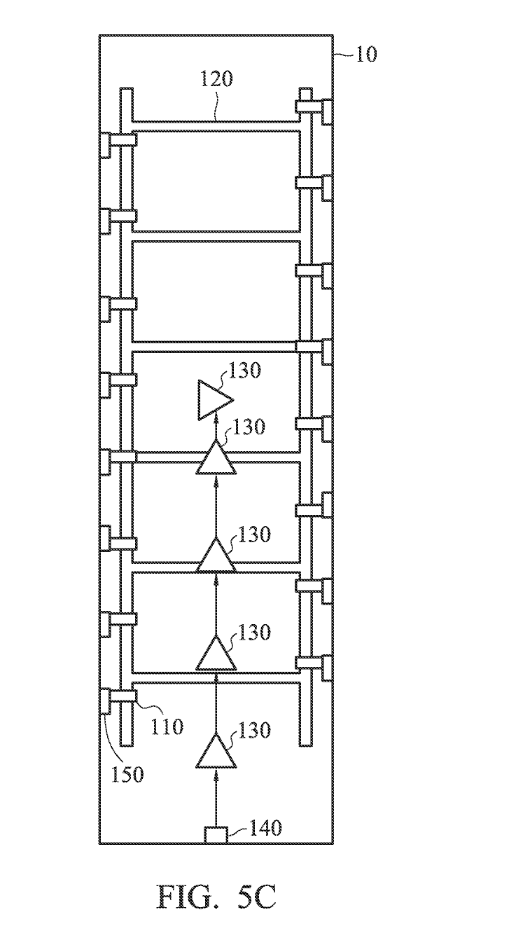

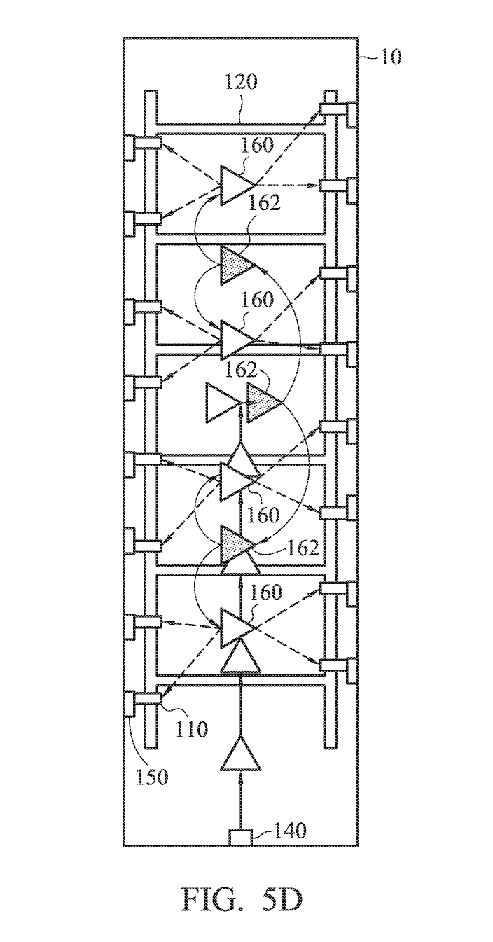

FIG. 5A to FIG. 5D are schematic diagrams illustrating the arrangements of the clock-distribution device 10 according to the present invention. As shown in FIG. 5A, the clock gates 110, buffer 130, the input port 140 and the output ports 150 are arranged in accordance with the registers 20 and the clock-generation device 30. Each of the clock gates is placed with each of the output ports 150, which means that the clock gates 110 are arranged to connect to the output ports 150 for transmitting the clock signals between the clock-distribution device 10 and the register 20. Afterwards, in the embodiment of FIG. 5B, a buffer tree consisting of several buffers 130 is arranged so that the clock signal could be transmitted from the input port 140 to the buffer 130. It should be noted the number of buffers 130 could be adjusted according to the configuration of the clock-distribution device 10. Afterwards, in the embodiment of FIG. 5C, the clock mesh 120 is arranged for uniformly distributing the clock signals to each of the clock gates 110. Afterwards, in the embodiment of FIG. 5D, the mesh drivers 160 and the pre-mesh drivers 162 are placed to drive the clock mesh 120.

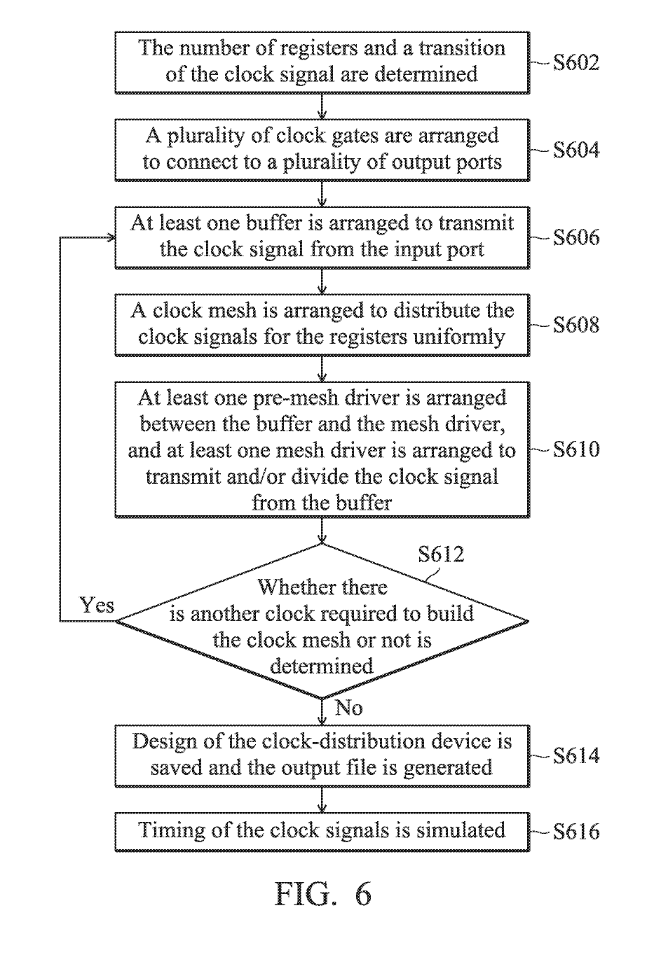

FIG. 6 is a flow chart illustrating the clock-distribution method according to the present invention. In step S602, the number of registers 20 and the transition of the clock signal are determined. Afterwards, in step S604, a plurality of clock gates 110 are arranged to connect to a plurality of output ports 150. In step S606, at least one buffer 130 is arranged to transmit the clock signal from an input port 140. Afterwards, a clock mesh 120 is arranged to distribute the clock signals for the registers 20 uniformly as shown in step S608. In step S610, at least one pre-mesh driver 162 is arranged between the buffer 130 and the the mesh driver 160, and at least one mesh driver 160 is arranged to transmit and/or divide the clock signal from the buffer 130.

In step S612, whether there is another clock required to build the clock mesh 120 or not is determined. If there is another clock required to build the clock mesh, step S606 to step S610 will be executed again. If there is not another clock required to build the clock mesh, once the clock routing for the clock mesh 120, the pre-mesh drivers 162 and the mesh drivers 160 is completed step S614 is executed that the design of the clock-distribution device 10 is saved and the output file is generated. Afterwards, in step S616, timing of the clock signals is simulated.

Although embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A clock-distribution device for dividing a clock signal into a plurality of clock signals for a plurality of registers, comprising:
a plurality of clock gates, utilized to transmit the clock signals to the registers; and
a clock mesh, arranged between the clock gates and an input port of the clock-distribution device, utilized to distribute the clock signals to the clock gates uniformly, wherein the clock signals are provided from the input port.

2. The clock-distribution device as claimed in claim 1, further comprising at least one mesh driver arranged between the clock mesh and the input port to drive the clock mesh.

3. The clock-distribution device as claimed in claim 2, further comprising at least one pre-mesh driver arranged between the mesh driver and the input port to drive the mesh driver.

4. The clock-distribution device as claimed in claim 3, wherein the number of mesh drivers and pre-mesh drivers is determined by the number of registers and/or transition of the clock signal.

5. The clock-distribution device as claimed in claim 3, further comprising at least one buffer arranged between the pre-mesh driver and the input port to transmit the clock signal from the input port to the pre-mesh driver.

6. The clock-distribution device as claimed in claim 1, wherein the input port is coupled to a clock-generation module to receive the clock signal generated by the clock- generation-module.

7. The clock-distribution device as claimed in claim 1, wherein the clock gates connect to a plurality of output ports of the clock-distribution device, and the clock-distribution device transmits the clock signals to the registers through the output ports.

8. The clock-distribution device as claimed in claim 1, wherein the number of clock gates is proportional to the number of registers.

9. The clock-distribution device as claimed in claim 1, wherein the configuration of the clock mesh is determined by the number of registers and/or transition of the clock signal.

10. A clock-distribution device for dividing a clock signal into a plurality of clock signals for a plurality of registers, comprising:
at least one mesh driver, coupled to an input port of the clock-distribution device to transmit and/or divide the clock signal from the input port; and
a clock mesh, driven by the mesh driver, utilized to distribute the clock signals for the registers uniformly.

11. The clock-distribution device as claimed in claim 10, wherein the configuration of the clock mesh and the number of clock meshes are determined by the number of registers and/or transition of the clock signal.

12. The clock-distribution device as claimed in claim 10, further comprising a plurality of clock gates coupled to the clock mesh, wherein the clock gates are utilized to transmit the clock signals to the registers.

13. The clock-distribution device as claimed in claim 12, wherein the number of clock gates is proportional to the number of registers.

14. A clock-distribution method for dividing a clock signal into a plurality of clock signals for a plurality of registers, comprising:
arranging a clock mesh to distribute the clock signals for the registers uniformly; and
arranging at least one mesh driver to transmit and/or divide the clock signal from an input port, wherein the mesh driver connects to the clock mesh to drive the clock mesh.

15. The clock-distribution method as claimed in claim 14, further comprising determining number of registers and a transition of the clock signal before the operations of arranging the clock mesh and arranging the mesh driver.

16. The clock-distribution method as claimed in claim 15, wherein the arrangement of the clock mesh and the arrangement of the mesh driver are based on the number of registers and the transition of the clock signal.

17. The clock-distribution method as claimed in claim 14, further comprising arranging at least one buffer between the mesh driver and the input port to transmit the clock signal from the input port to the mesh driver before the operations of arranging the clock mesh and arranging the mesh driver.

18. The clock-distribution method as claimed in claim 17, further comprising arranging a plurality of clock gates which connect to a plurality of output ports before the operation of arranging at least one buffer.

19. The clock-distribution method as claimed in claim 14, further comprising routing the clock mesh after the operations of arranging the clock mesh and arranging the mesh driver.

20. The clock-distribution method as claimed in claim 19, further comprising simulating timing of the clock signals after the operations of routing the clock mesh.
